(19) United States
(12) Patent Application Publication
(10) Pub. No.: US 2024/0348011 A1
(43) Pub. Date: Oct. 17, 2024

(54) Cat's-eye swept source laser with integrated lens and mirror

(71) Applicant: KineoLabs, Billerica, MA (US)

(72) Inventors: Dale C. Flanders, Lexington, MA (US); Walid A. Atia, Jamaica Plain, MA (US); J. Grant Houston, Lexington, MA (US)

(21) Appl. No.: 18/632,718

(22) Filed: Apr. 11, 2024

Related U.S. Application Data
(60) Provisional application No. 63/495,628, filed on Apr. 12, 2023.

(51) Int. Cl. H01S 5/14; H01S 5/026

(52) U.S. Cl. CPC H01S 5/141; H01S 5/0267

(57) ABSTRACT

A tunable or swept laser architecture that is appropriate for swept source optical coherence tomography and other applications including spectroscopy employing a cat's-eye configuration with a preferably transmissive tilt tuned interference thin film filter. A cavity element is used in the laser. It has a front surface and a back surface, the front surface being configured to receive the collimated light and the back surface comprising a mirror or output coupler surface.

### RELATED APPLICATIONS

This application claims the benefit under 35 USC 119 (e) of U.S. Provisional Application No. 63/495,628, filed on Apr. 12, 2023, which is incorporated herein by reference in its entirety.

### BACKGROUND OF THE INVENTION

The use of the cat's-eye laser architecture for optical coherence tomography (OCT) and spectroscopy, for example, has been documented in U.S. patent application Ser. Nos. 18/184,015 and 18/184,019, filed on Mar. 15, 2023 by Atia and Flanders, which applications are incorporated herein by this reference. This is an old architecture that was documented in an article entitled “Interference-filter-tuned alignment-stabilized, semiconductor external-cavity laser,” by Zorabedian and Trutna in Optics Letters, Vo. 13, No. 10, October 1988.

### SUMMARY OF THE INVENTION

An important metric for tunable lasers is the smoothness of the power as the laser is tuned over its wavelength scan or sweep band. For both spectroscopy and OCT, among other uses, this tuning curve is preferably smooth.

Ripple in the tuning curve is often indicative of parasitic cavities either within the laser's nominal cavity or external cavities that create feedback.

Parasitic cavities are usually addressed with well-designed antireflective coatings for lenses and other elements in the laser's cavity. The gain chip's front facet will be coated along with any lenses in the cavities.

Nevertheless, the coatings are not perfect, so ripple can be controlled by reducing the number of surfaces in the cavity.

The present invention concerns an integrated cat's-eye lens and end mirror. This reduces the number of surfaces in the cavity and also lowers part counts and simplifies laser construction by replacing two or more discrete elements with a single one.

In general, according to one aspect, the invention features a tunable laser system comprising a gain chip for amplifying light in a laser cavity, a collimating lens for collimating light from the gain chip, and a cavity element functioning both as an end reflector of the laser cavity and as a focusing lens for focusing the collimated light on the end reflector.

In general, according to another aspect, the invention features tunable a laser system comprising a gain chip for laser amplification, a collimating lens for collimating laser light, a cavity element with a front surface and a back surface, the front surface being configured to receive the collimated light and the back surface comprising a mirror or output coupler surface. An interference bandpass filter is further provided for tuning the wavelength of the laser light.

In examples, the cavity element is a cat's-eye laser cavity element. Usually, a front surface of the cavity element is antireflection coated.

In some cases, the cavity element includes one or more graded index lenses.

Usually, an angle control actuator is provided for changing the angle of the bandpass filter to the collimated light to change the passband of the filter. Often this is some type of motor, such as a galvanometer such as a servo galvanometer. A rotating motor or servomotor is also an option.

In general, according to another aspect, the invention features a method of tuning a wavelength of a tunable laser system laser. The method comprises providing a gain chip for laser amplification, collimating the laser light with a collimating lens, receiving the collimated light at a front surface of a cavity element, reflecting the light off a mirror or output coupler surface at the back surface of the cavity element, passing the light through an interference bandpass filter, and changing the angle of the bandpass filter to the collimated light to change the passband of the filter.

Other aspects potentially encompass the gain chip, which can be a GaAlAs chip. A pass band of the thin film bandpass filter is often between 0.05 nanometers (nm) and 5 nm wide, full width at half maximum (FWHM). A pass band of the thin film bandpass filter can be between 0.1 nm and 2 nm wide, FWHM. Usually, a diameter of the collimated light is greater than 1 or 2 millimeters (mm).

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1A is a schematic side view of a cat's-eye tunable laser according to the present invention;

FIG. 1B is a schematic side view of a cat's-eye tunable laser employing a servo galvanometer;

FIGS. 2A, 2B, and 2C are schematic top views of gain chips for the tunable lasers;

FIG. 3 is a schematic side view of a cat's-eye tunable laser according to a second embodiment;

FIG. 4 is a schematic side view of a cat's-eye tunable laser according to third embodiment;

FIG. 5 is a schematic side view of a cat's-eye tunable laser according to fourth embodiment;

FIG. 6A is a schematic plot of transmission as a function of frequency showing the passband of the bandpass filter; and

FIG. 6B is a plot of tilt angle as a function of center wavelength for the bandpass filter.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Also, all conjunctions used are to be understood in the most inclusive sense possible. Thus, the word “or” should be understood as having the definition of a logical “or” rather than that of a logical “exclusive or” unless the context clearly necessitates otherwise. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It will be understood that although terms such as “first” and “second” are used herein to describe various elements, these elements should not be limited by these terms. These terms are only used to distinguish one element from another element. Thus, an element discussed below could be termed a second element, and similarly, a second element may be termed a first element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

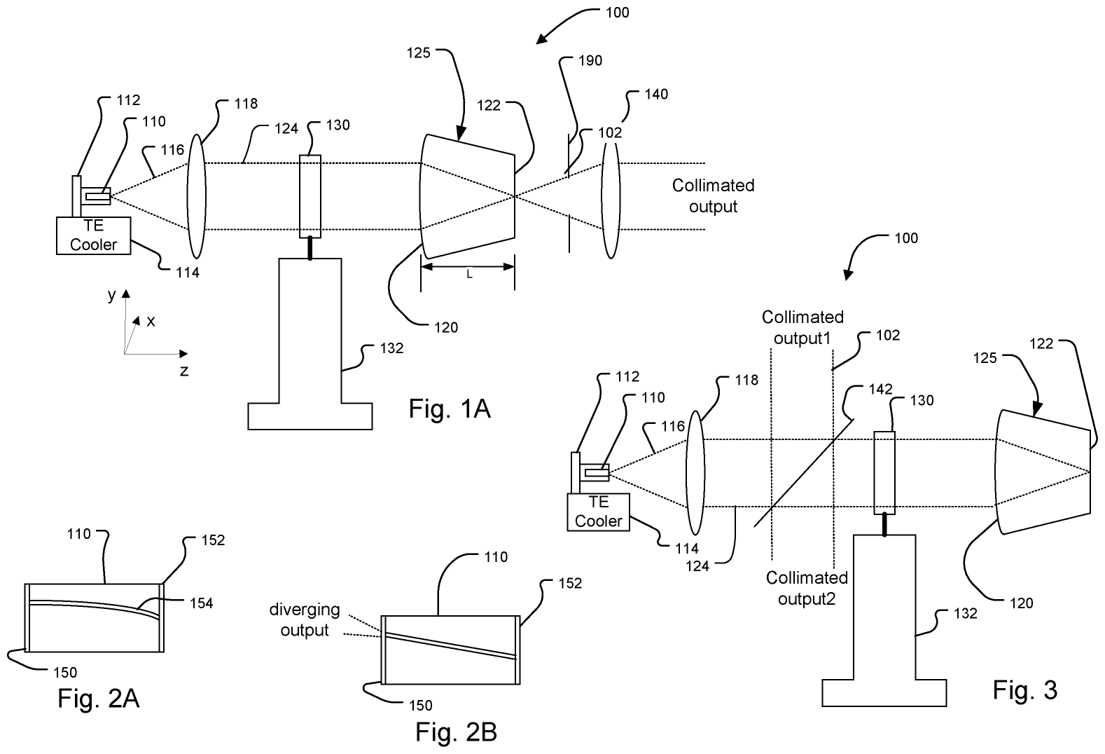

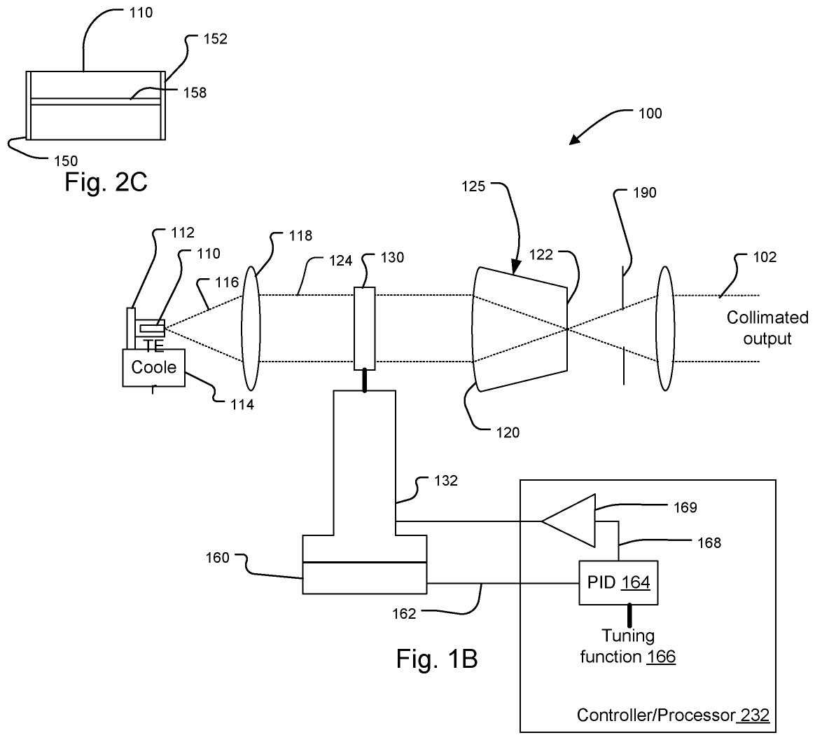

FIG. 1A shows a tunable laser 100 that is sometimes referred to as a cat's-eye laser, which has been constructed according to the principles of the present invention.

The laser's amplification is provided by a GaAlAs gain chip 110, in one example. The gain chip 110 amplifies light in the wavelength range of about 800 to 900 nanometers. Preferably its center wavelength is around 840 nanometers, which is useful for applications such as ophthalmic imaging and other diagnostic uses because of the water window (650 to 950 nm) at these wavelengths. Another advantage of this wavelength range is that it can be detected with standard cameras with silicon-based imager chips. Specifically, the output is detected with silicon, e.g., complementary metal-oxide-semiconductor (CMOS) or charge-coupled device CCD, imagers.

Other material systems can be selected for the gain chip, however. Common material systems are based on III-V semiconductor materials, including binary materials, such as GaN, GaAs, InP, GaSb, InAs, as well as ternary, quaternary, and pentenary alloys, such as InGaN, InAlGaN, InGaP, AlGaAs, InGaAs, GaInNAs, GaInNAsSb, AlInGaAs, InGaAsP, AlGaAsSb, AlGaInAsSb, AlAsSb, InGaSb, InAsSb, and InGaAsSb. Collectively, these material systems support operating wavelengths from about 400 nanometers (nm) to 2500 nm, including longer wavelength ranges extending into multiple micrometer wavelengths. These other wavelengths are especially useful when employing the laser 100 in a tunable laser spectrometry. Semiconductor quantum well, quantum cascade and quantum dot gain regions are typically used to obtain especially wide gain and spectral emission bandwidths, and support operation up to 250 μm in wavelength. Quantum well layers may be purposely strained or unstrained depending on the exact materials and the desired wavelength coverage.

In the preferred current embodiment, the gain chip 110 is mounted in a TO-can type or other hermetic package 112. This protects the chip 110 from dust and the ambient environment including moisture. In some examples, the TO-can or butterfly package has an integrated or a separate thermoelectric cooler 114.

The free space beam 116 from the package 112 is diverging in both axes (x, y). It is collimated by a collimating lens 118. The resulting collimated beam is received by a cat's eye cavity element 125.

The bulk material of the cavity element is a material that is transparent at the operation wavelength of the laser. Often this is a glass or plastic (such as acrylic). The front surface 120 of the cavity element 125 is convex to focus the light onto a cat's eye mirror/output coupler surface 122. The front surface 120 of the cavity element 125 is preferably antireflection AR coated to minimize reflections, improving power and reducing tuning curve ripple.

Antireflection coatings are vital for lenses in lasers as they help minimize the amount of light loss during transmission. These coatings are designed to reduce the amount of light reflected back into the laser cavity, which can cause significant losses in the overall efficiency of the laser system.

Generally, when light passes into a material, a portion of it is reflected back due to the difference in refractive indices between the air and the material. This reflection can lead to a significant reduction in the amount of light that is transmitted, resulting in a decrease in the overall laser power.

The antireflection coating on surface 120 includes thin layer(s) that help reduce the amount of reflection that occurs. These layers are designed to have a refractive index that is between that of the air and the lens, which helps to minimize the reflection of the light.

In the present case, the antireflection coating is deposited using a combination of thin film deposition techniques such as electron beam evaporation, sputtering, or chemical vapor deposition. These techniques are used to deposit a series of thin layers with varying refractive indices onto the surface of the lens.

The number and thickness of these layers are chosen to create a thin film interference stack that will minimize the amount of reflection that occurs at the surface of the lens. The thickness and refractive index of each layer are designed to be a quarter-wavelength thick at the desired wavelength of light in the mid or near-infrared region. Preferably the thin film interference stack includes two or more layers.

The backside of the cavity element 125, which includes a planar output coupler mirror surface 122, is flat and defines the other end of the laser cavity, extending between the mirror/output coupler surface 122 and the back/reflective facet of the gain chip 110.

The length L of the cavity element 125 is sized based on the refractive index of the material and the curvature of the cat's eye mirror/output coupler surface 122 so that the beam is at a focus at the mirror/output coupler surface 122.

In other embodiments, output coupler mirror surface 122 is curved with a spherical or paraboloid curvature. This curvature ensures the focal point of the light from front surface 120 is focused at the surface of the output coupler mirror surface 122 even with slight movement of the beam due to some angle-dependent refractive walk-off occurring in the thin film interference bandpass filter 130 as its angle changes.

The collimated light 124 between the collimating lens 118 and the cavity element 125 passes through the thin film interference bandpass filter 130. This provides a pass band of approximately 0.3 nanometers (nm) full width at half maximum (FWHM). More generally, its pass band is between 0.2 nm and 0.5 nm FWHM, or more generally between 0.1 nm and 2 nm FWHM. Even more generally, it is between 0.05 nm to 5 nm FWHM.

The bandpass filter is held on an arm of an angle control actuator 132 that changes the angle of the bandpass filter 130 to the collimated light 124. In one example, the angle control actuator is a galvanometer. In other examples, the angle control actuator 132 is a servomotor or an electrical motor that continuously spins the bandpass filter 130 in the collimated beam 124. This allows for tilting of the bandpass filter 130 with respect to the collimated beam 124 to thereby tilt-tune the filter and thus change the passband to scan or sweep the wavelength of the swept laser 100. Typically, the angle control actuator tilts the angle of the bandpass filter 130 in a range of less than 60 degrees to the beam and greater than 0 degrees. In most operations, the angle control actuator tilts the bandpass filter between 50 degrees and 10 degrees.

Tuning speed specifications for a galvanometer generally range from 0.1 Hz to 50 kHz. For the higher speeds, a 25 kHz resonant galvanometer can be used with bi-directional tuning, but higher and lower speeds can be used. Wavelength tuning speed is usually given in nm/see, so for a 100 Hz tuning speed ideal for retinal imaging applications where a line-speed camera at 100 kHz will give 1000 sampled bandwidth points and 70 nm tuning range, this would give 70 nm/10 msec=7000 nm/sec. In general, the tuning speed should be between 3,000 nm/see and 11,000 nm/see or higher.

For retinal or industrial imaging with low-cost CMOS cameras, 840 nm center wavelength is an ideal water window. The tuning range is usually minimally 30 nm of tuning range. Preferably, the tuning range is closer to 60 nm or 70 nm or more. This provides good resolution of <8 micrometers in air. In general, the tuning range should be between 30 nm and 100 nm.

The size of the collimated beam 124 is important for many applications. As a general rule, a smaller beam results in higher divergence resulting in a larger cone half angle (CHA). This reduces the minimum line width over angle for a tunable filter. In the current embodiment, the collimated beam is preferably not less than, i.e., greater than, 1 millimeter (mm) FWHM and is preferably greater than 2 mm FWHM for retinal OCT application. It can be smaller, however, for many spectroscopy applications in the infrared, visible or ultraviolet. In general, the CHA should be less than 0.04×0.02 degrees and preferably about 0.02×0.01 degrees or less. Also, the beam size needs to be large enough to have enough multi-passes through the filter and not suffer losses (larger beam has lower divergence and thus will have lower losses in a higher finesse/narrower linewidth filter). A fairly small impact will result here given the large beam size (small CHA).

The light from the gain chip is polarized. In the common architectures, the polarization is horizontal or parallel to the epitaxial layers of the edge-emitting gain chip 110. In the preferred configuration, the filter is oriented to receive the S polarization in order to maintain narrow line width of the filter as it is tilt tuned. On the other hand, the P polarization broadens drastically at large tilt angles. S polarization has higher loss at larger tilt angles than P. So, the filter design needs to address these issues by providing a low enough loss across the tuning band for S, in the current embodiment.

On the other hand, for spectroscopy, P polarization configurations might be desirable due to the higher powers across the scanband.

In general, the present cat's-eye configuration provides a number of advantages. It provides low loss, low tolerance, repeatable stable operation since it provides for a lower angle wavelength change over grating-based lasers.

The mirror/output coupler surface 122 of the cavity element 125 will typically be coated with a dielectric interference coating to reflect about 80% of the light back into the laser's cavity and transmit about 20% of light. More generally, the coating of the mirror/output coupler surface 122 can reflect from 10% to 99% of light (transmitting 90% to 1%, respectively), depending on the output power and laser cavity loss desired. Higher reflectivity results in lower loss cavities and thus wider laser tuning range where gain exceeds loss, but results in lower output power. In typical operation, the coating of the mirror/output coupler surface 122 reflects less than 90%.

Partially reflecting dielectric coatings such as the coating on the mirror/output coupler surface 122 of cavity element 125 are constructed using a similar process to antireflection coatings. They are designed to reflect a portion of the incident light while transmitting the rest.

The construction of partially reflecting dielectric coatings on surface 122 involves depositing a series of alternating layers of high and low refractive index materials onto surface 122 of the substrate. The number, thickness, and refractive index of each layer are carefully chosen to create a multilayer stack that reflects a specific portion of the incident light while transmitting the rest.

The thickness of the layers is chosen to be a quarter-wavelength of the desired wavelength of light. By controlling the number, thickness, and refractive index of each layer, the coating reflects a specific percentage of the incident light.

A partially reflecting metal layer is an alternative but generally not preferred because of the concomitant losses associated with metal mirrors.

In some embodiments, an iris or mask 190 is added typically after the mirror output coupler 122 to clip the beam edge. This reduces power fluctuations as the beam wanders due to refraction in the tilting bandpass filter 130. Preferably, it is between 80% and 95% and preferably about 90% of the beam size.

Typically, the diverging beam from the mirror output coupler 122 is collimated with an output collimating lens 140 to form a free space output beam 102.

FIG. 1B shows a preferred implementation of the tunable laser 100 and specifically the angle control actuator 132.

The angle control actuator 132 is operated as a servomechanism. In the illustrated embodiment, the angle control actuator 132 is a servo controlled galvanometer with an encoder 160. The encoder 160 produces an angle signal 162 indicating the angle of the galvanometer and thus the filter 130 to the collimated beam 124. Preferably, the encoder is an optical encoder and is often analog.

A controller/processor receives the angle signal 162 at a PID (proportional-integral-derivative) controller 164. The PID controller 164 compares the angle signal 164 to a specified tuning function. Often this is sawtooth or triangular waveform. The PID controller 166 produces the control function 168 that is used to drive the windings of the galvanometer 132 via an amplifier 169.

FIG. 2A shows a preferred gain chip architecture. This chip 110 is termed a single angled facet (SAF) edge-emitting chip. As such, it has a high reflectivity (HR) coated rear facet 150. It has an antireflective (AR) coated front facet 152. In addition, for improved performance, it has a curved ridge waveguide 154 that is perpendicular to the rear facet 150 but is angled at the interface with the front facet 152. This angling at the front facet along with the AR coating reduces reflections at the front facet reflectivity by up to 40 dB and significantly improves laser performance by reducing parasitic reflections that can otherwise lead to non-smooth tuning and mode-hopping.

FIG. 2B shows another potential edge emitting gain chip configuration. The basic configuration is termed a semiconductor optical amplifier (SOA) gain chip. As such, it has an AR coated rear facet and an AR coated front facet. Its straight but angled ridge waveguide 156 intersects with the facets at an angle to minimize reflections back into the chip. In one example, its back facet light is coupled to a lens or pair of lenses and a mirror which reflects light to return through the lens and to the chip. The mirror could be made partially reflecting to take the output out from the back facet.

FIG. 2C shows another potential gain chip configuration. The basic configuration is termed a Fabry-Perot gain chip. As such, it has an HR coated rear facet 150 and an AR coated front facet 152. The straight ridge waveguide 158 intersects with the front facet 152 at a perpendicular angle and thus does create some internal reflections that can affect performance.

FIG. 3 shows another example of the laser 100. Here the one or more outputs are taken within the laser's cavity. Specifically, an angled beam splitter 142 picks off part of the light in the laser's cavity as collimated output beams output1 and output2. The coating of the mirror/output coupler surface 122 typically has high reflectivity, such as higher than 99%, unless it is used to provide a third output, in which case this coating has a reflectivity of about 90% or less.

As discussed, the output coupler is often implemented as a beam splitter. The output coupling is then chosen by selecting an output coupler with the desired ratio of reflectivity versus transmissivity. Another option is to use the combination of a polarization beam splitter and a quarter waveplate. This allows for adjustability in the output coupling by controlling the angle of the quarter waveplate.

In this configuration, there are actually two outputs: collimated output1 and collimated output2. Generally, collimated output1 will provide higher power since it receives light directly from the chip. This output is also characterized by a higher amplified spontaneous emission (ASE) spectra. On the other hand, collimated output2 will exhibit a lower higher power, but this output is characterized by a lower spectral sideband since it takes light after double passing through the bandpass filter. Note also that in this configuration the output light's position does not deviate while the filter angle is tuned because the light is reflected back through the filter and retraces itself.

In this example, an integrated k clock is possible. An etalon is added in one output. A trigger signal is then created that a camera can use for efficient sampling without the need for software resampling.

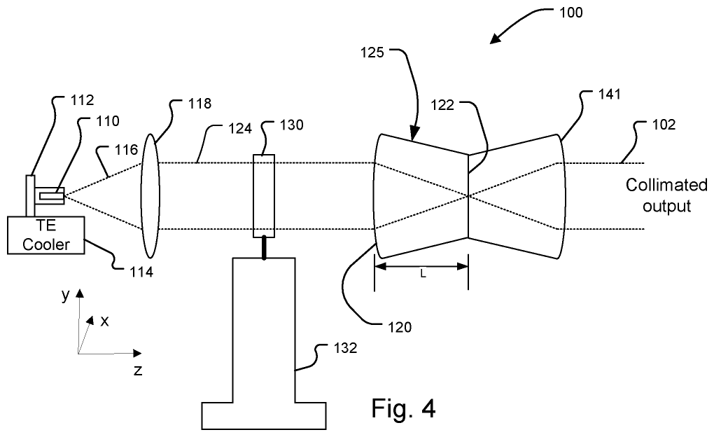

FIG. 4 shows another embodiment of the cavity element 125. It includes two pieces bonded to each other at the cat's eye mirror/output coupler surface 122. Output surface 141 performs the function of the collimating lens 140.

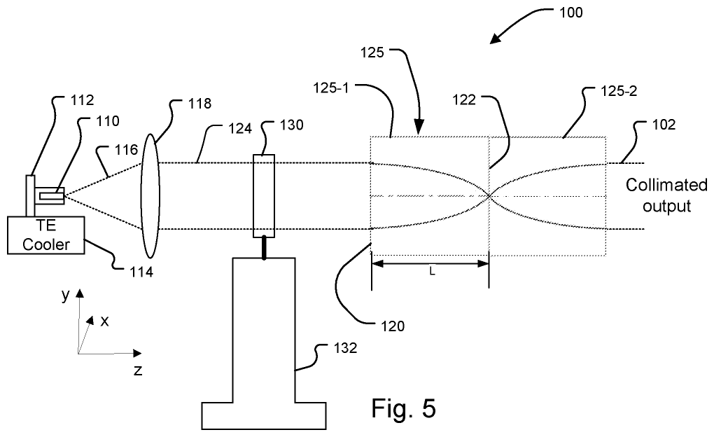

FIG. 5 shows another embodiment in which the cavity element is implemented with one or more graded index (GRIN) lenses.

The cavity element includes a first GRIN lens element 125-1. The length L of the first GRIN lens element 125-1 is sized so that light comes to a focus at its backside 122. This is often referred to as a quarter pitch lens. The front surface 120 first GRIN lens element 125-1 is preferably antireflection AR coated to minimize reflections, improving power and reducing tuning curve ripple. The front surface preferably also has a wedge angle of at least 0.2 degrees and is often greater to prevent parasitic reflections at this interface.

The backside of first GRIN lens element 125-1 includes a planar output coupler mirror surface 122 which is flat and defines the other end of the laser cavity, extending between the mirror/output coupler surface 122 and the back/reflective facet of the gain chip 110.

A second GRIN lens 125-2 (shown), a single mode optical fiber or a multimode optical fiber in different examples, is bonded to the mirror surface 122 of the first GRIN lens element 125-1 to produce a collimated beam or to transmit the output remote in the case of fiber.

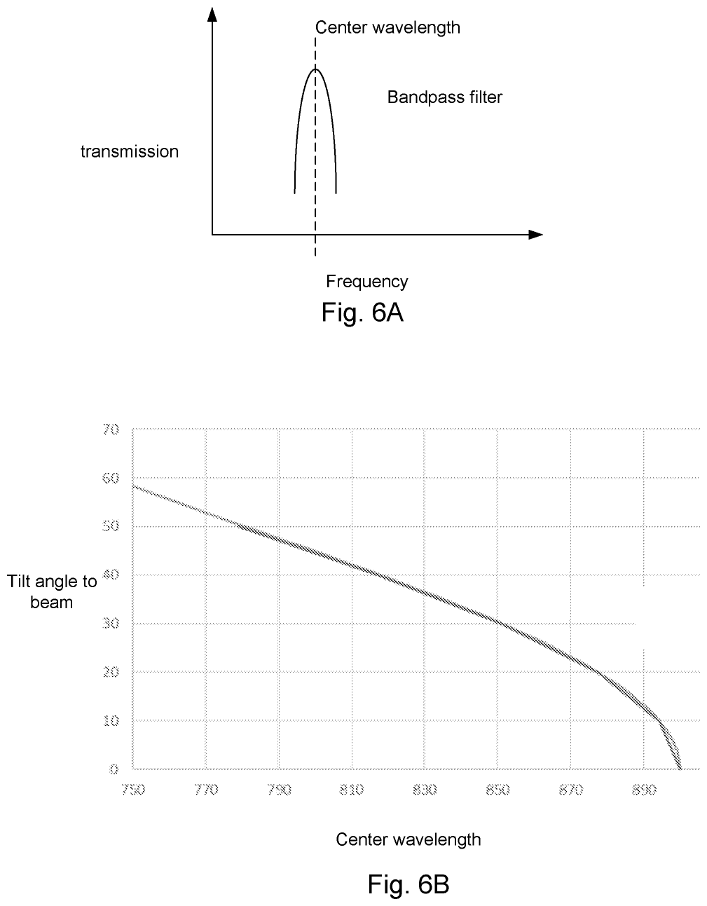

FIG. 6A a plot of transmission as a function of frequency for the passband filter at a specified angle. It shows the narrow passband.

FIG. 6B is a plot of angle of the filter 130 to the beam as a function of the passband wavelength for S polarization. It shows how the passband can be tuned by the galvanometer tilting of the passband filter.

The following formula relates the passband wavelength as a function of the center wavelength with no tilt, and θ, which is the angle between the beam and the filter.

$${λ}_{θ} = {λ}_{o} \sqrt{1 - {( \frac{{n}_{o}}{{n}_{eff}} sin θ )}^{2}}$$

The forgoing formula shows how the filter exhibits a slow tilt angle at low angles then gets faster. Operation is preferable in the more linear region to minimize the required tilt angle and have a more linear scan. The illustrated filter function is for a laser operating in the 810-870 nm tuning range. So 900 nm is chosen for 0 degree incidence wavelength. Thus, it will have the smallest operating angle around 870 nm and tune from 810-870 nm. Note that angle tuning always reduces the wavelength. N_{eff} is adjustable and can be helpful to amplify the tuning with angle.

While this invention has been particularly shown and described with references to preferred embodiments thereof, it will be understood by those skilled in the art that various changes in form and details may be made therein without departing from the scope of the invention encompassed by the appended claims.

What is claimed is:

1. A tunable laser system, comprising:
a gain chip for amplifying light in a laser cavity;
a collimating lens for collimating light from the gain chip;
a cavity element functioning as an end reflector of the laser cavity and a focusing lens for focusing the collimated light on the end reflector.

2. The tunable laser system of claim 1, further including an interference bandpass filter for tuning a wavelength of the laser.

3. The tunable laser system of claim 1, wherein the cavity element is a cat's-eye laser cavity element.

4. The tunable laser system of claim 1, wherein a front surface of the cavity element is antireflection coated.

5. The tunable laser system of claim 1, wherein the cavity element includes one or more graded index lenses.

6. A tunable laser system, comprising:
a gain chip for laser amplification;
a collimating lens for collimating laser light from the gain chip;
a cavity element with a front surface and a back surface, the front surface configured to receive the collimated light and the back surface comprising a mirror/output coupler surface;
an interference bandpass filter for tuning the wavelength of the laser light; and
an angle control actuator for changing the angle of the bandpass filter to the collimated light to change the passband of the filter.

7. The tunable laser system of claim 6, wherein the angle control actuator is a galvanometer.

8. The tunable laser system of claim 6, wherein the angle control actuator is a servomotor.

9. A method of tuning a wavelength of a tunable laser system, comprising:
providing a gain chip for laser amplification;
collimating the laser light with a collimating lens;
receiving the collimated light at a front surface of a cavity element;
reflecting the light off a mirror or output coupler surface at the back surface of the cavity element;
passing the light through an interference bandpass filter; and
changing the angle of the bandpass filter to the collimated light to change the passband of the filter.

10. The method of claim 9, wherein the gain chip is a GaAlAs chip.

11. The method of claim 9, wherein a pass band of the bandpass filter is between 0.05 nanometers (nm) and 5 nm wide, full width at half maximum (FWHM).

12. The method of claim 9, wherein a pass band of the bandpass filter is between 0.1 nm and 2 nm wide, FWHM.

13. The method of claim 9, wherein a diameter of the collimated light is greater than 1 millimeter (mm).

14. The method of claim 9, wherein a diameter of the collimated light is greater than 2 mm.
